(19) United States
(12) Patent Application Publication
(10) Pub. No.: US 2010/0032702 A1
(43) Pub. Date: Feb. 11, 2010

(54) Light-Emitting Diode Housing Comprising Fluoropolymer

(75) Inventor: Jacob Lahijani, Wilmington, DE (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E. I. DU PONT DE NEMOURS AND COMPANY, Wilmington, DE (US)

(21) Appl. No.: 12/533,511

(22) Filed: Jul. 31, 2009

Related U.S. Application Data
(60) Provisional application No. 61/087,815, filed on Aug. 11, 2008.
(60) Provisional application No. 61/161,778, filed on Mar. 20, 2009.

(51) Int. Cl. H01L 33/00

(52) U.S. Cl. 257/98; 257/E33.067

(57) ABSTRACT

A light-emitting diode housing comprising fluoropolymer is disclosed. The light-emitting diode housing supports a light-emitting diode chip and reflects at least a portion of the light emitted from the light-emitting diode chip.

### FIELD OF THE DISCLOSURE

This disclosure relates to a light-emitting diode housing comprising fluoropolymer for supporting a light-emitting diode chip and reflecting at least a portion of the light emitted from the light-emitting diode chip.

### BACKGROUND

Semi-conductor light emitting devices, such as light-emitting diodes (LEDs) and laser diodes (LDs), are among the most efficient and robust light sources currently available.

Light extraction is a key issue for light-emitting devices. A common problem with semiconductor light-emitting devices is that the efficiency with which light may be extracted from the device is reduced due to internal reflection in the interface between the device and the surroundings, followed by reabsorption of the reflected light in the device.

Light-emitting diode (LED) housings are conventionally constructed from engineering plastics such as polyphenylhydrazine (PPA) to which titanium dioxide is added to increase the visible light reflectance of the housing. However, titanium dioxide causes PPA to discolor (yellow) with use over time, resulting in overall LED efficiency drop and change in emitted color.

Thus, there is a need for a LED housing which is highly reflective of visible light and has high color retention.

For high efficiency light extraction, it is advantageous if the light extracting materials are in direct contact with the LED. However, in high intensity applications, where single solid-state LED with an effect of up to 3 watts per square mm or arrays of such LEDs with a total effect of up to 100 watts or more, substantial heat is generated by the LEDs. Temperatures of up to 250° C. are reached in such high intensity LEDs.

For LED housings, it would be advantageous to be able to use materials that can accommodate higher processing temperatures, for example to increase the range of different materials which can be used, and in steps of attaching other components, such as for example lenses, during LED encapsulation.

Thus, there is a need for LED housing material which is melt processible at temperatures below those that would damage LED chip elements, and further, is thermally stable during LED assembly and over long periods of time at the elevated operating temperatures common to high intensity LEDs.

### SUMMARY

Described herein is an LED housing that meets industry needs.

The present LED housing comprises fluoropolymer that is highly reflective of visible light, melt processible, and color stable, and that can withstand, for example, solder processing temperatures of about 260° C. for times in excess of 15 minutes.

Briefly stated, and in accordance with one aspect of the present invention, there is provided a light-emitting diode housing for supporting a light-emitting diode chip and reflecting at least a portion of the light emitted from the light-emitting diode chip, wherein the housing comprises fluoropolymer.

Pursuant to another aspect of the present invention, there is provided a light-emitting diode having a light-emitting diode chip supported by a light-emitting diode housing that reflects at least a portion of the light emitted by the light-emitting diode chip, wherein the housing comprises fluoropolymer.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts presented herein.

FIG. 1 illustrates a cross-sectional view of an embodiment of a light-emitting diode housing.

FIG. 2 illustrates a cross-sectional view of an embodiment of a light-emitting diode housing of the present invention.

FIG. 3 illustrates a cross-sectional view of an embodiment of a light-emitting diode of the present invention comprising a light-emitting diode chip supported by a light-emitting diode housing of the present invention.

Skilled artisans appreciate that objects in the figures are illustrated for simplicity and clarity and have not been drawn to scale. The dimensions of some of the features in the figures are exaggerated relative to other features to help to improve understanding.

While the present invention will be described in connection with a preferred embodiment thereof, it will be understood that it is not intended to limit the invention to that embodiment. On the contrary, it is intended to cover all alternatives, modifications, and equivalents as may be included within the spirit and scope of the invention as defined by the appended claims.

### DETAILED DESCRIPTION

In an embodiment of the light-emitting diode housing, the fluoropolymer comprises a melt processible semicrystalline perfluoropolymer.

In another embodiment of the light-emitting diode housing, the fluoropolymer further comprises a filler dispersed in the fluoropolymer. In another embodiment of the light-emitting diode housing, the filler comprises a scatterer of visible light. In another embodiment of the light-emitting diode housing, the scatterer of visible light comprises a white pigment. In another embodiment of the light-emitting diode housing, the fluoropolymer further comprises from about 0.1 to about 40 weight percent white pigment, based on the combined weight (alternatively, “total weight percent”) of the fluoropolymer and the white pigment. In another embodiment of the light-emitting diode housing where the fluoropolymer further comprises white pigment, the photopic reflectance over the wavelength range of 380 nm to 780 nm of the light-emitting diode housing is at least about 95%.

In another embodiment of the light-emitting diode housing, the photopic reflectance over the wavelength range of 380 nm to 780 nm of the fluoropolymer is at least about 80%, more preferably 90%, and most preferably 95%.

In another embodiment of the light-emitting diode housing, the fluoropolymer further comprises a filler for modifying the flexural modulus of the fluoropolymer. In another embodiment of the light-emitting diode housing, the fluoropolymer further comprises a filler for modifying the coefficient of linear thermal expansion of the fluoropolymer. In another embodiment of the light-emitting diode housing the fluoropolymer further comprises a filler for modifying the thermal conductivity of the fluoropolymer. In another embodiment of the light-emitting diode housing, the filler are glass fibers. In another embodiment of the light-emitting diode housing, the filler are hollow glass microspheres.

In another embodiment of the light-emitting diode housing, the fluoropolymer further comprises a luminescent compound.

Embodiments described above are merely exemplary and not limiting. After reading this specification, skilled artisans appreciate that other aspects and embodiments are possible without departing from the scope of the invention.

Other features and benefits of one or more of the embodiments will be apparent from the following detailed description, and from the claims. The detailed description addresses: 1. Definitions and Clarification of Terms; 2. Light-Emitting Diode (LED) Housing; 3. Fluoropolymer Comprising the Light-Emitting Diode (LED) Housing; 4. Filler; and Examples.

### 1. Definitions and Clarification of Terms

Before addressing details of embodiments described below, some terms are defined or clarified.

By light-emitting diode is meant a diode emitting light in any wavelength interval from and including UV-light to infrared light, and is also taken to include laser diodes.

By filler is meant any compound that can be added to the fluoropolymer to modify the physical properties of the fluoropolymer.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Unless otherwise defined, all technical and scientific terms used herein have the same meaning as commonly understood by one of ordinary skill in the art to which the claims belong. Although methods and materials similar or equivalent to those described herein can be used in the practice or testing of the embodiments disclosed, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials and processing acts are conventional and may be found in textbooks and other sources within the LED art.

### 2. Light-Emitting Diode (LED) Housing

The present LED housing serves several functions. One function is to support an LED chip in a desired position and orientation while the LED is arranged on a substrate or connected to circuitry. Another function is to reflect back in the direction benefiting from illumination, light emitted from a light-emitting diode chip that is directed towards the housing (i.e., light directed away from the direction benefiting from illumination), and in so doing increase the overall luminance of the LED. Another function is to dissipate heat generated by an LED chip (e.g., a high intensity LED chip operating at a high temperature) away from the LED chip so as to protect the LED chip from damage from excessive heat.

In another embodiment, a function of the LED housing is to reflect and convert the color of the light directed at the housing into a desired color. For example, for converting blue light into green or red light, or for converting UV-light into blue, green or red light. In such an embodiment, the fluoropolymer comprising the housing further comprises at least one luminescent compound. Luminescent compounds suitable for incorporation into the fluoropolymer for this purpose, and their amount, are known to those skilled in the art. In another embodiment, luminescent compounds comprise silicon nitride compounds, such as Sr₂Si₅N₈ doped with europium, aluminum or oxygen. In another embodiment, luminescent compounds comprise yttrium-aluminum-garnet doped with cerium, praseodymium, europium or combinations thereof, for example (YAG:Ce), (YAG:Ce,Pr), and (YAG:Ce,Eu). As used herein, the term luminescent compound comprises both fluorescent and phosphorescent compounds, which absorbs light of a wavelength or wavelength interval and emits light of another wavelength or wavelength interval.

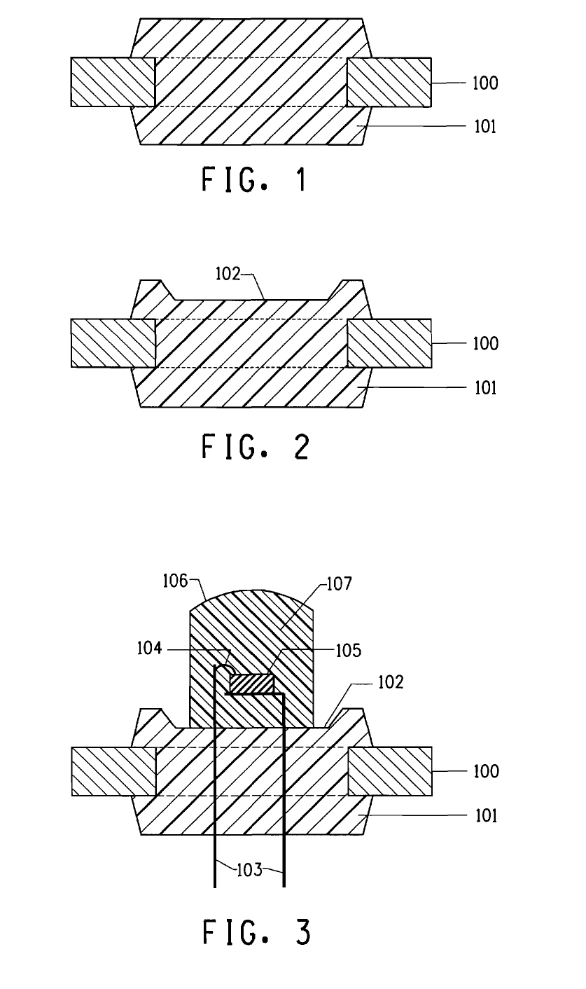

FIG. 1 illustrates a cross-sectional view of one embodiment of a light-emitting diode housing of the present invention. A metal frame 100 contains an injection molded light-emitting diode housing 101 comprising fluoropolymer that extends through an opening in the metal frame 100.

In another embodiment, the LED housing 101 has at least one recess. The recess is sized such that at least one LED chip and lens assembly fits within the recess, and is arranged in a desired location allowing for connection to the associated circuitry. Thus, FIG. 2 illustrates a cross-sectional view of one embodiment of the present invention of a light-emitting diode housing. A metal frame 100 contains an injection molded light-emitting diode housing 101 comprising fluoropolymer that extends through an opening in the metal frame 100. The light-emitting diode housing 101 contains a recess 102 for location of a light-emitting diode chip and lens assembly. The shape and dimensions of the recess 102, for example, the depth and angle of the walls of the recess 102, can be adjusted to control the angle and direction of reflection and to maximize the reflection of at least a portion of the light emitted by a light-emitting diode chip that is directed toward the housing 101.

In another embodiment, each LED chip is arranged in a separate recess within an LED housing, and the walls of the recesses position and orient each LED chip. In another embodiment, more than one LED chip can be arranged in a single recess. In such a case, the positioning and orientating, for example, can be constituted by elements which prevents LEDs from moving or rotating in the plane of the LEDs, but which do not form walls separating the recess into a plurality of recesses.

FIG. 3 includes, as illustration, a cross-sectional view of one embodiment of a light-emitting diode of the present invention. A metal frame 100 contains an injection molded light-emitting diode housing 101 comprising fluoropolymer that extends through an opening in the metal frame 100. The light-emitting diode housing 101 contains a recess 102. Electrodes 103, one via a gold wire 104, connect to a light-emitting diode chip 105 located within the recess 102. A lens 106 comprising polymer 107 encapsulates the light-emitting diode chip 105 and directs light emitted by the light-emitting diode chip 105 in a direction benefiting from illumination. The housing 101 supports and maintains in place the light-emitting diode chip 105 and lens 106, as well as reflects back in a direction benefiting from illumination light emitted from the light-emitting diode chip 105 that is directed towards the housing 101. In some embodiments, there is substantially no space between the bottom of the light-emitting diode chip 105 and the adjacent face of the injection molded light-emitting diode housing 101. In some embodiments, the light-emitting diode chip 105 and lens 106 are attached to the adjacent face of the light-emitting diode housing 101 with adhesive.

LED chips of utility for use with the present LED housing include LED chips capable of emitting light in the range from ultra-violet to infrared light. Example LED chips of utility include those constructed by growing n/p light-emitting layers on a crystalline substrate, such as sapphire (single crystal alumina). LEDs chips of utility include blue or UV emitting diode chips, as blue/UV light easily can be converted into light of other colors by luminescent compounds.

High-power LED chips, with an effect of 3 watts per square mm or more, are also of utility with the present LED housing.

LEDs containing the present fluoropolymer light-emitting diode housing have utility in articles benefitting from an LED light source, including, for example: telephones (e.g., cell phone backlights, cell phone key pads)); optical displays (e.g., LCD television and computer monitor backlights, large scale video displays, light source for DLP and LCD projectors); transportation (e.g., bicycle, motorcycle and automobile lighting, train and aircraft interior lighting); general lighting (e.g., home, office, architectural and street lighting); instrumentation (e.g., laboratory and electronics test equipment); as well as miscellaneous appliances and applications such as light bulbs, watches, flashlights, calculators, strobe lights, camera flashes, flatbed scanners, barcode scanners, remote controls for TVs, VCRs and DVRs using infrared LEDs, light sources for machine vision systems, medical lighting where IR-radiation and high temperatures are unwanted, infrared illumination for night vision security cameras, and movement sensors, such as an optical computer mouse.

### 3. Fluoropolymer Comprising the Light-Emitting Diode (LED) Housing

The present LED housing 101 comprises fluoropolymer. In some embodiments, the LED housing comprises at least about 30% fluoropolymer by weight, based on the weight of all materials comprising the LED housing. In other embodiments, the LED housing comprises at least about 65% fluoropolymer by weight, based on the weight of all materials comprising the LED housing. In other embodiments, the LED housing comprises at least about 75% fluoropolymer by weight, based on the weight of all materials comprising the LED housing. In other embodiments, the LED housing comprises at least about 90% fluoropolymer by weight, based on the weight of all materials comprising the LED housing. In other embodiments, the LED housing comprises at least about 95% fluoropolymer by weight, based on the weight of all materials comprising the LED housing. In other embodiments, the LED housing comprises at least about 99% fluoropolymer by weight, based on the weight of all materials comprising the LED housing. In other embodiments, the LED housing comprises about 100% fluoropolymer by weight. In other embodiments, the LED housing consists essentially of fluoropolymer. That is to say, the LED housing contains fluoropolymer and no other material that would materially affect the basic and novel characteristics of the LED housing. In other embodiments, the LED housing comprises from about 65% to about 90% fluoropolymer by weight, based on the weight of all materials comprising the LED housing. In other embodiments, the LED housing comprises from about 50% to about 90% fluoropolymer by weight, based on the weight of all materials comprising the LED housing. In other embodiments, the LED housing comprises from about 30% to about 95% fluoropolymer by weight, based on the weight of all materials comprising the LED housing. In other embodiments, the LED housing comprises from about 30% to about 99% fluoropolymer by weight, based on the weight of all materials comprising the LED housing.

Generally, fluoropolymer of utility in the present LED housing is/has: 1.) melt processible and injection moldable, suitable for formation of an LED housing by conventional injection molding technology; 2.) heat resistant, able to withstand high temperatures generated by high-power LED chips, as well as high temperatures used in steps of LED assembly, such as soldering at temperatures such as 260-280° C. for periods of time up to about 15 minutes, as well as curing (e.g., of curable epoxy-based materials used to form an LED lens) temperatures of about 150° C. for periods of time from 1 to 4 hours; 3.) low warpage after such periods of time at such temperatures; and 4.) photopic reflectance over the wavelength range of 380 nm to 780 nm of at least about 80%, more preferably 90%, and most preferably 95%.

Fluoropolymer meeting these criteria and of utility in the present LED housing are melt extrudable and injection moldable, and have a melt flow rate of about 1.5 to about 40 g/10 min. Melt flow rate (MFR) can be determined by ASTM method D1238-04c. Fluoropolymers can be made by polymerization of at least one fluorinated monomer by known methods. In one embodiment, fluoropolymers include copolymers of a fluorinated monomer having 2 to 8 carbon atoms, with one or more polymerizable comonomers having 2 to 8 carbon atoms. Hydrocarbon monomers of utility include, for example, ethylene and propylene. Fluorinated monomers of utility include, for example, tetrafluoroethylene (TFE), vinylidene fluoride (VDF), hexafluoroisobutylene (HFIB), hexafluoropropylene (HFP) and perfluoro(alkyl vinyl ether) (PAVE) in which the perfluoroalkyl group contains 1 to 5 carbon atoms and is linear or branched. In another embodiment, PAVE monomers of utility can be represented by the formula CF₂=CFOR or CF₂=CFOR′OR, wherein R is perfluorinated linear or branched alkyl groups having 1 to 5 carbon atoms, and R′ is perfluorinated linear or branched alkylene groups having 1 to 5 carbon atoms. In another embodiment, R groups have 1 to 4 carbon atoms. In another embodiment, R′ groups have 2 to 4 carbon atoms. Example PAVE monomers include perfluoro(methyl vinyl ether) (PMVE), perfluoro(ethyl vinyl ether) (PEVE), perfluoro(propyl vinyl ether) (PPVE), and perfluoro(butyl vinyl ether) (PBVE). In another embodiment, fluoropolymer can be made using more than one PAVE monomer, such as the TFE/PMVE/PPVE copolymer, sometimes called MFA by the manufacturer.

In another embodiment, fluoropolymer comprises perfluorinated ethylene-propylene (FEP), the copolymer of tetrafluoroethylene and hexafluoropropylene sold under the trademark TEFLON® FEP by DuPont. In another embodiment, the HFP content is about 5 to about 17 weight percent in the TFE/HFP fluoropolymer. In another embodiment, FEP fluoropolymer comprises TFE/HFP/PAVE wherein the HFP content is about 5 to about 17 weight percent and the PAVE content, preferably PEVE, is about 0.2 to about 4 weight percent, the balance being TFE, to total 100 weight percent for the fluoropolymer.

In another embodiment, fluoropolymer comprises perfluoroalkoxy fluorocarbon resin (PFA), the copolymer of tetrafluoroethylene and perfluoro(alkyl vinyl ether), sold under the trademark TEFLON® PFA by DuPont. In another embodiment, fluoropolymer is a TFE/PAVE fluoropolymer, commonly known as PFA, having at least about 2 weight percent PAVE of the total weight per cent, including when the PAVE is PPVE or PEVE, and typically contain about 2 to about 15 weight percent PAVE. In another embodiment, the PAVE includes PMVE, and the composition is about 0.5 to about 13 weight percent perfluoro(methyl vinyl ether), and about 0.5 to about 3 weight percent PPVE, the remainder of the total of 100 weight percent being TFE. This product is generally referred to as MFA.

In another embodiment, fluoropolymer comprises polyvinylidene fluoride, commonly referred to as PVDF.

In another embodiment, fluoropolymer comprises copolymers of vinylidene fluoride and HFP, optionally containing TFE, commonly referred to as THV.

In another embodiment, fluoropolymer comprises ethylene tetrafluoroethylene (ETFE), the copolymer of ethylene and tetrafluoroethylene sold under the trademark TEFZEL® by DuPont.

In another embodiment, fluoropolymer comprises copolymers of ethylene, tetrafluoroethylene, and hexafluoropropylene (EFEP).

In another embodiment, fluoropolymer comprises copolymers of vinyl fluoride.

In another embodiment, fluoropolymer comprises polychlorotrifluoroethylene (PCTFE), the homopolymer of chlorotrifluoroethylene.

In another embodiment, fluoropolymer comprises polychlorotrifluoroethylene-ethylene (ECTFE), the copolymer of chlorotrifluoroethylene and ethylene.

In another embodiment, fluoropolymer can be subjected to fluorination for the purpose of reducing the number of unstable end groups (e.g., carboxylic acid end groups). The fluorination can be carried out by known methods with a variety of fluorine radical generating compounds under a variety of conditions as is known in the art.

Examples of commercially available fluoropolymers of utility include Tefzel® ETFE grade 207, Teflon® FEP grades 100, TE-9494, 100J, and 6100n, and Teflon® PFA grades 340, 440 and 3000 (all of these fluoropolymers are manufactured by E.I. du Pont de Nemours & Co., Wilmington, Del.)

### 4. Filler

In an embodiment of the present light-emitting diode housing, the fluoropolymer further comprises a filler dispersed in the fluoropolymer. By filler is meant any compound that can be added to the fluoropolymer to modify the physical properties, including the optical, mechanical and thermal properties of the fluoropolymer. In one embodiment each filler modifies a single physical property of the fluoropolymer. In another embodiment, each filler modifies more than one physical property of the fluoropolymer. For example, filler comprising titanium dioxide can increase both the photopic reflectance and the thermal conductivity of the fluoropolymer.

The shape of the filler is not particularly limited, and can be for example, micro-scale fibers, filaments, flakes, whiskers, tubes, particulates, spheres and the like. In another embodiment, the filler is hollow. In another embodiment, the filler is solid.

Fillers can be present in the fluoropolymer in any amount sufficient to modify the physical properties of the fluoropolymer. In another embodiment, the amount of the filler ranges from about 1% to about 70% by weight, based on the combined weight of the filler and fluoropolymer. In another embodiment, the amount of the filler ranges from about 5% to about 70% by weight, based on the combined weight of the filler and fluoropolymer. In another embodiment, the amount of the filler ranges from about 10% to about 50% by weight, based on the combined weight of the filler and fluoropolymer. In another embodiment, the amount of the filler ranges from about 10% to about 35% by weight, based on the combined weight of the filler and fluoropolymer.

### 4.1 Filler for Modifying the Optical Properties of the Fluoropolymer

In one embodiment of the present LED housing, the fluoropolymer further comprises a filler, dispersed in the fluoropolymer, and the filler comprises a scatterer of visible light for modifying the optical properties of the fluoropolymer. In this embodiment, scatterer is in a dispersed state throughout the fluoropolymer. In one embodiment, each scatterer is surrounded by fluoropolymer and not in physical contact with other scatterers. In one embodiment scatterer are particles (herein alternately referred to as particulate scatterer). In another embodiment scatterer are particles and voids present in the fluoropolymer arising from particles being present in the fluoropolymer above the critical pigment volume concentration.

The light scattering cross section per unit scatterer volume of fluoropolymer containing scatterer depends strongly on the difference between the refractive index of the scatterer and the fluoropolymer. A larger light scattering cross section is preferred and can be obtained by maximizing the difference between the refractive index of the scatterer and the fluoropolymer. In another embodiment the difference between the refractive index of the scatterer and the fluoropolymer is at least about 0.5. In another embodiment the difference between the refractive index of the scatterer and the fluoropolymer is at least about 1.

The refractive index of particulate scatterer of utility in the present LED is at least about 1.5. High refractive index particulate scatterer has a refractive index of at least about 2.0. In another embodiment, high refractive index particulate scatterer has a refractive index of at least about 2.5. Particulate scatterer having a refractive index less than that of the high refractive index particulate scatterer may be referred to herein as low refractive index particulate scatterer. Voids have a refractive index of 1.0, which is the refractive index of air contained within the voids.

Scatterer shape is not particularly limited, and may be for example, spherical, cubic, aciculate, discal, scale-like, fibrous and the like. While such shapes can be useful for creating voids, spherical shape is preferred for high refractive index particulate scatterer.

Scatterer can be solid or hollow. Voids can arise from the use of hollow particles (i.e. having internal voids), such as hollow sphere glass or plastic particles.

Particles having low absorption of visible light that function to scatter visible light are of utility as scatterer in the present LED housing. Particles include those conventionally known as white pigments. If the refractive index of the particles is substantially the same as the refractive index of the fluoropolymer comprising the housing (e.g., low refractive index particulate scatterer where the refractive index difference between the binder and scatterer is less than about 0.5), then such particles will generally not function effectively as scatterer at concentrations below their CPVC (critical pigment volume concentration) in the fluoropolymer. However, such particles are of utility for creating light scattering voids when included in the fluoropolymer in an amount above the CPVC. High refractive index particulate scatterer, for example titanium dioxide, is highly effective in scattering light even in the substantial absence of voids when used in the fluoropolymer in an amount below the CPVC.

The light scattering cross section per unit scatterer volume of fluoropolymer containing closely spaced scatterer is maximized when the number average mean diameter of the scatterer is slightly less than one-half the wavelength of the incident light. The diameter of particles of utility as scatterer in the fluoropolymer comprising the present LED housing can be measured by conventional sedimentation or light scattering methodology. For high refractive index particulate scatterer, in another embodiment the particle number average mean diameter is about 0.1 μm to about 30 μm. In another embodiment, the particle number average mean diameter of high refractive index particulate scatterer is about 0.2 μm to about 1 μm. In another embodiment where high refractive index particulate scatterer is used, the visible light reflectance of the present fluoropolymer is maximized when the particles have a number average mean diameter of about 0.2 μm to about 0.4 μm.

Particulate scatterer of utility in the present LED housing has low absorption of visible light. By low absorption is meant that scatterer has lower absorption than fluoropolymer or does not substantially contribute to the absorption of the fluoropolymer. In another embodiment, the present LED housing comprising fluoropolymer and scatterer has an absorption coefficient of about 10⁻³ m²/g or less. In another embodiment, the present LED housing comprising fluoropolymer and scatterer has an absorption coefficient of about 10⁻⁵ m²/g or less. In another embodiment where scatterer comprises titanium dioxide, the absorption coefficient of the LED housing comprising fluoropolymer and scatterer is about 10⁻³ m²/g or less at wavelengths from about 425 nm to about 780 nm. In another embodiment where scatterer comprises titanium dioxide, the absorption coefficient of the LED housing comprising fluoropolymer and scatterer is about 10⁻⁵ m²/g or less at wavelengths from about 425 nm to about 780 nm.

The constitution of particles of utility as scatterer in the present fluoropolymer housing is not particularly limited, and includes, for example, metal salts, metal hydroxides and metal oxides. Included are, for example: metal salts such as barium sulfate, calcium sulfate, magnesium sulfate, aluminum sulfate, barium carbonate, calcium carbonate, magnesium chloride, magnesium carbonate; metal hydroxides such as magnesium hydroxide, aluminum hydroxide and calcium hydroxide; and metal oxides such as calcium oxide, magnesium oxide, alumina and silica. Additionally, clays such as kaolin, alumina silicates, calcium silicate, cements, zeolites and talc are also of utility. Plastic pigments are also of utility. In another embodiment, high refractive index particulate scatterer comprise white pigment particles including at least one of titanium dioxide and zinc oxide. Titanium dioxide has the highest light scattering cross section per unit volume as well as low absorption of visible light. An example of a commercially available titanium dioxide of utility is Ti-Pure® R-900 produced by DuPont.

The amount of scatterer dispersed in the fluoropolymer directly impacts the photopic reflectance of the fluoropolymer. If the amount of scatterer in the fluoropolymer is too small, then the scatterer does not substantially contribute to the photopic reflectance of the fluoropolymer. If the amount of scatterer in the fluoropolymer is too large, then the physical properties of the housing comprising the fluoropolymer can be adversely affected and the housing can, for example, become undesirably brittle.

In another embodiment where the scatterer is white pigment, the amount of the white pigment is about 5 to about 20 weight percent, based on the combined weight of the fluoropolymer and the white pigment.

In another embodiment where the scatterer is white pigment, the amount of the white pigment is about 8 to about 12 weight percent, based on the combined weight of the fluoropolymer and the white pigment.

In another embodiment where the scatterer is white pigment, the amount of the white pigment is about 10 weight percent, based on the combined weight (or alternatively use, “total weight percent”) of the fluoropolymer and the white pigment.

In some embodiments, the photopic reflectance over the wavelength range of 380 nm to 780 nm of the fluoropolymer containing filler for modifying the optical properties of the fluoropolymer is at least about 80%. In some embodiments, the photopic reflectance over the wavelength range of 380 nm to 780 nm of the fluoropolymer containing filler for modifying the optical properties of the fluoropolymer is at least about 85%. In some embodiments, the photopic reflectance over the wavelength range of 380 nm to 780 nm of the fluoropolymer containing filler for modifying the optical properties of the fluoropolymer is at least about 90%. In some embodiments, the photopic reflectance over the wavelength range of 380 nm to 780 nm of the fluoropolymer containing filler for modifying the optical properties of the fluoropolymer is at least about 95%.

### 4.2 Filler for Modifying the Mechanical Properties of the Fluoropolymer

In one embodiment, the fluoropolymer contains a filler for modifying the mechanical properties of the fluoropolymer.

Solid fluoropolymer typically has a thermal expansion of about 10⁻⁴ K⁻¹ whereas metal (e.g., such as copper, which in another embodiment can comprise metal frame 100) to which the LED housing is attached has a thermal expansion of about 10⁻⁵ K⁻¹. Thus, a temperature change of 100K, for example, as might be encountered when soldering a metal frame containing a LED housing to a circuit board, leads to a strain mismatch of 1% between the two materials. In another embodiment, the present LED housing and a metal frame to which it is attached are in contiguous contact, and such temperature change can lead to the development of internal stresses, in particular at fluoropolymer-metal interfaces. These stresses can undesirably promote the formation and the growth of cracks in the fluoropolymer and can cause the separation or delamination of the LED housing from the metal frame.

Thus, in some embodiments, filler can be used to modify the coefficient of linear thermal expansion (CTE) of the fluoropolymer so that the CTE of the filled fluoropolymer is substantially identical to the CTE of the material to which the light-emitting diode housing is attached (e.g., a metal, such as copper, frame (e.g., metal frame 100)). By substantially identical is meant that fluoropolymer containing such filler has a CTE that allows for the combination of the LED housing and material to which it is attached to be manipulated while being heated without substantially affecting the structural integrity or disrupting the contiguous contact of the LED housing and the material to which it is attached. In some embodiments, the CTE of the fluoropolymer is within 25% of the CTE of the metal. In some embodiments, the CTE of the fluoropolymer is within 20% of the CTE of the metal. In some embodiments, the CTE of the fluoropolymer is within 10% of the CTE of the metal.

In another embodiment, filler can be used to modify the flexural modulus of the fluoropolymer so that the flexural modulus of the filled fluoropolymer is greater than the flexural modulus of the material to which the LED housing comprising filled fluoropolymer is attached. By greater than is meant that the material to which the LED housing is attached can be manipulated (e.g., bent) without substantially effecting the structural integrity of the LED housing.

Conventional fillers known for modifying the mechanical properties of polymers are contemplated here for modifying the mechanical properties of the fluoropolymer. Fillers of utility include metal (or metal alloy) powders, metal oxides and other metal-containing compounds, metalloid oxides and other metalloid-containing compounds, organic polymers and the like or blends thereof.

Examples of metal (or metal alloy) powders of utility as filler include, bismuth powder, brass powder, bronze powder, cobalt powder, copper powder, Inconel metal powder, iron metal powder, manganese metal powder, molybdenum powder, nickel powder, stainless steel powder, titanium metal powder, zirconium metal powder, tungsten metal powder, beryllium metal powder, zinc metal powder, magnesium metal powder, or tin metal powder.

Examples of metal oxides and other metal-containing compounds of utility as filler include but are not limited to zinc oxide, zinc sulfide, iron oxide, aluminum oxide, titanium dioxide, magnesium oxide, zirconium oxide, barium sulfate, tungsten trioxide, clay, talc, silicates such as calcium silicate, diatomaceous earth, calcium carbonate and magnesium carbonate.

Examples of metalloid oxides and other metalloid-containing compounds of utility as filler include boron powder, boron nitride, silica, silicon nitride, and glass fibers.

Examples of organic polymers of utility as filler include polyether ketones, such as PEK, PEEK and PEKK, and aramid fibers. Further included is high molecular weight, melt-processible or non melt-processible (e.g., sinterable) polytetrafluoroethylene (PTFE) microparticles as filler for modifying the processibility and physical properties of the fluoropolymer. For example, fluoropolymer can comprise a major amount of PFA and a minor amount of a PTFE micropowder dispersed therein, for example, ZONYL® fluoroadditive grade MP1600 (MFR 17 g/10 min, melt viscosity of 3×10³ Pa·s at 372° C.) available from DuPont.

In another embodiment, filler comprises glass fiber for modifying the flexural modulus of the fluoropolymer so that the flexural modulus of the filled fluoropolymer is greater than the flexural modulus of the material to which the LED housing comprising filled fluoropolymer is attached. An example of glass fiber of utility is high performance E-glass chopped strand grade 910 made by Saint-Gobain Vetrotex America.

In another embodiment, the filler comprises hollow glass microspheres for modifying the flexural modulus of the fluoropolymer so that the flexural modulus of the filled fluoropolymer is greater than the flexural modulus of the material to which the LED housing comprising filled fluoropolymer is attached. An example of glass microspheres of utility is W-210 grade of Zeeospheres™ Ceramic Microspheres, made by 3M.

### 4.3 Filler for Modifying the Thermal Properties of the Fluoropolymer

In one embodiment, the fluoropolymer contains a filler for modifying the thermal conductivity of the fluoropolymer.

Solid fluoropolymer typically has a thermal conductivity of about 0.24 W/m·K, whereas metal, e.g., such as copper, which in another embodiment can comprise metal frame 100 to which the LED housing is attached, has a thermal conductivity of about 386 W/m·K. Thus, fluoropolymer is thermally insulating relative to other materials that comprise an LED device. In an embodiment where a LED housing contains a high intensity LED chip, it is preferred that the housing dissipate heat generated by the LED chip away from the LED chip so as to protect the LED chip from damage caused by the buildup of excessive heat.

Thus, in some embodiments, filler can be used to modify the thermal conductivity of the fluoropolymer so that the thermal conductivity of the filled fluoropolymer results in the more efficient dissipation of heat generated by the LED chip away from the LED chip.

Conventional fillers known for modifying the thermal conductivity of polymers are contemplated here as being of utility for modifying the thermal conductivity of the fluoropolymer. Fillers of utility include those earlier disclosed herein as being of utility for modifying the optical and mechanical properties of the fluoropolymer. Thus fillers of utility for modifying the thermal conductivity of the fluoropolymer include metal salts, metal hydroxides, metal oxides, metal (or metal alloy) powders, metal oxides and other metal-containing compounds, metalloid oxides and other metalloid-containing compounds, organic polymers and the like or blends thereof.

### EXAMPLES

The concepts described herein will be further described in the following examples, which do not limit the scope of the invention described in the claims.

### Example 1

Teflon® PFA 340 polymer (fluoropolymer available from DuPont) was dry blended with 10% by weight of Ti-Pure® R900 titanium dioxide (available from DuPont). This mixture was then fed thorough a Brabender single screw extruder having a 1.5 inch inner bore diameter and a Saxon mixing section at the screw tip. The screw RPM ranged from 30 to 100. The extruder temperature profile was from 316° C. (600° F.) at the inlet to 382° C. (720° F.) at the outlet. The temperature profile of the molten fluoropolymer in the extruder ranged from 343° C. (650° F.) at the inlet to 416° C. (780° F.). The extrudate strand is cut with a cutter at the extruder outlet to form pellets. The photopic reflectance over the wavelength range of 380 nm to 780 nm of the extruded fluoropolymer is 96%. The pellets are then injection molded (under standard PFA injection molding conditions) to make LED housings.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification is to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

What is claimed is:

1. A light-emitting diode housing for supporting a light-emitting diode chip and reflecting at least a portion of the light emitted from said light-emitting diode chip, wherein said light-emitting diode housing comprises fluoropolymer.

2. A light-emitting diode comprising a light-emitting diode chip supported by said light-emitting diode housing of claim 1.

3. The light-emitting diode housing of claim 1, wherein said light-emitting diode housing comprises at least about 30% fluoropolymer by weight, based on the weight of all materials comprising said light-emitting diode housing.

4. The light-emitting diode housing of claim 1, wherein said fluoropolymer comprises a melt processible semicrystalline perfluoropolymer.

5. The light-emitting diode housing of claim 1, wherein said fluoropolymer further comprises a filler dispersed in said fluoropolymer.

6. The light-emitting diode housing of claim 5, wherein said filler comprises a scatterer of visible light.

7. The light-emitting diode housing of claim 6, wherein said scatterer of visible light comprises a white pigment.

8. The light-emitting diode housing of claim 7, wherein said white pigment comprises titanium dioxide.

9. The light-emitting diode housing of claim 7, wherein the amount of said white pigment is from about 0.1 to about 40 weight percent, based on the combined weight of said fluoropolymer and said white pigment.

10. The light-emitting diode housing of claim 7, wherein the photopic reflectance over the wavelength range of 380 nm to 780 nm of said light-emitting diode housing is at least about 95%.

11. The light-emitting diode housing of claim 1, wherein the photopic reflectance over the wavelength range of 380 nm to 780 nm of said fluoropolymer is at least about 80%.

12. The light-emitting diode housing of claim 5, wherein said filler modifies the flexural modulus of said fluoropolymer.

13. The light-emitting diode housing of claim 5, wherein said filler modifies the coefficient of linear thermal expansion of said fluoropolymer.

14. The light-emitting diode housing of claim 5, wherein said filler modifies the thermal conductivity of said fluoropolymer.

15. The light-emitting diode housing of claim 5, wherein the amount of said filler is from about 1 to about 70 weight percent, based on the combined weight of said fluoropolymer and said filler.

16. The light-emitting diode housing of claim 5, wherein said filler comprises glass fibers.

17. The light-emitting diode housing of claim 5, wherein said filler comprises hollow glass microspheres.

18. The light-emitting diode housing of claim 1, wherein said fluoropolymer further comprises a luminescent compound.
